(19) United States
(12) Patent Application Publication
(10) Pub. No.: US 2007/0018653 A1
(43) Pub. Date: Jan. 25, 2007

(54) Apparatus and method for testing system board

(75) Inventor: Yun-ho Choi, Suwon-si (KR)

Correspondence Address: STEIN, MCEWEN & BUI, LLP, 1400 EYE STREET, NW, SUITE 300, WASHINGTON, DC, 20005, US

(73) Assignee: Samsung Electronics Co., Ltd., Suwon-si (KR)

(21) Appl. No.: 11/473,029

(22) Filed: Jun. 23, 2006

(30) Foreign Application Priority Data
Jul. 23, 2005 (KR) 2005-67093

(51) Int. Cl. G01R 31/00

(52) U.S. Cl. 324/500

(57) ABSTRACT

An apparatus for testing a system board includes a sensing unit that detects a predetermined signal output from the system board, and a control-signal-output unit that outputs a predetermined control signal to the system board in correspondence with the predetermined signal detected by the sensing unit. A method for testing a system board includes detecting a predetermined signal output from the system board; and outputting a predetermined control signal to the system board in correspondence with the detected predetermined signal

### CROSS-REFERENCE TO RELATED APPLICATION

This application is based on and claims priority from Korean Patent Application No. 2005-67093, filed on Jul. 23, 2005, the disclosure of which is incorporated herein in its entirety by reference.

### BACKGROUND OF THE INVENTION

1. Field of the Invention

Aspects of the present invention relate generally to an apparatus and a method of testing a system board, and more particularly to an apparatus and a method of testing a system board through an automatic process.

2. Description of the Related Art

To meet the demand for personal computers and notebook computers, the system boards that are used in the personal computers and notebook computers are mass produced. When manufacturing a system board, problems may occur due to process defects or failure of electronic parts mounted on the system board. Therefore, it is necessary to test the system board in order to check the basic functions of the system board. Such test work for the system board can be performed in a final step of the system board manufacturing process, or just before assembling the computer that uses the system board.

When testing the system board, a control signal must be input into the system board from an external device such as a system board test apparatus. Conventionally, a worker must connect the system board to the system board test apparatus. The system board is tested in relation to various test items and a discrete control signal is required for each test item.

Conventionally, the worker connects a keyboard connector of the system board to a keyboard or a keyboard emulator provided in the system board test apparatus. If necessary, the worker also connects a monitor connector of the system board to a display unit provided in the system board test apparatus.

After connecting the system board to the system board test apparatus, the worker operates the keyboard emulator of the system board test apparatus or the keyboard in order to output a control signal. The control signal output from the system board test apparatus is transmitted to the keyboard connector of the system board connected to the system board test apparatus. Thus, test work for the system board is performed according to the control signal.

When the test work for one test item has been finished, the system board requests a test result and a control signal through the monitor connector in order to prepare the test work for the next test item. The test result and the content of the control signal are displayed on the display unit connected to the monitor connector. At this time, the worker checks the display unit of the system board test apparatus, and manipulates the keyboard or the keyboard emulator provided in the system board test apparatus, thereby outputting the control signal in order to perform the test work for the next test item.

However, according to the conventional practice, the worker must manually generate each of the control signals in order to perform the test work for each of the test items. Accordingly, if the worker makes a mistake or performs other work during the test work, the system board that is subject to the test work, must be kept waiting for a predetermined time until a proper control signal has been input into the system board from the worker, thereby lowering productivity. In particular, since one worker may operate a plurality of system board test apparatuses simultaneously, such a problem may become serious.

### SUMMARY OF THE INVENTION

Accordingly, aspects of the present invention have been created to solve the above-mentioned problems occurring in the conventional practice, and to provide an apparatus and a method that tests a system board through an automatic process.

According to an aspect of the present invention, there is provided an apparatus that tests a system board, including: a sensing unit that detects a predetermined signal output by the system board; and a control-signal-output unit that outputs a predetermined control signal to the system board corresponding to the predetermined signal detected by the sensing unit.

According to another aspect of the present invention, there is provided a method of testing a system board, comprising: detecting a predetermined signal output from the system board; and outputting a predetermined control signal that corresponds with the detected predetermined signal to the system board.

According to another aspect of the present invention, there is provided a system board comprising electrical parts including a memory unit, a processor, and an emission device; an wiring interconnecting the memory unit, the processor, and the emission device, wherein the memory stores a predetermined program encoded with a test method implemented by the processor, the test method comprising, when the system board is connected to an apparatus that tests the system board, the processor performs the predetermined program required to initiate a test work and outputs a predetermined signal through the emission device to the apparatus to perform at least one test included in the test work to be performed on the system board.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a flowchart schematically illustrating a procedure of manufacturing a system board according to an aspect of the invention;

FIG. 2 is a schematic view illustrating the relationship between a system board and a system board test apparatus according to an embodiment of the present invention;

FIGS. 3A and 3B are views illustrating the status of light-emitting diodes and test items corresponding to the status of the light-emitting diodes;

FIGS. 4A and 4B are views illustrating the status of sound signals generated by a speaker and test items corresponding to the status of the sound signals;

FIG. 5 is a block view illustrating a system board test apparatus according to an embodiment of the present invention; and

FIG. 6 is a flowchart illustrating the procedure of testing a system board according to an embodiment of the present invention.

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures.

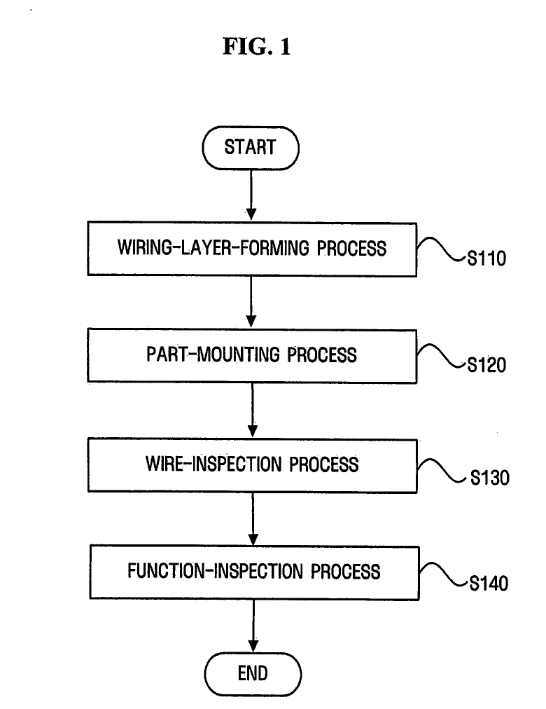

FIG. 1 is a flowchart schematically illustrating the procedure of manufacturing a system board.

As shown in FIG. 1, the manufacturing procedure for the system board mainly includes a wiring layer forming process S110, a part mounting process S120, a wire inspection process S130 and a function-test process S140. It is to be understood that these processes can be performed by one entity in one location or can be performed by multiple entities or performed in multiple locations.

In the wiring layer forming process S110, a conductive line is coated on the system board. The conductive line electrically interconnects the electronic parts mounted on the system board. The conductive line can be variously designed according to the type and position of the electronic parts mounted on the system board.

After basic wiring has been formed on the system board through the wiring layer forming process S110, the part mounting process S120 is performed. In the part mounting process S120, various electronic parts are mounted on the system board formed with a wiring layer. By way of non-limiting examples, electronic parts may include integrated circuits, (such as, for example, a CPU (central processing unit) and a memory), electronic devices, (such as, for example, a resistor and a condenser), and connectors, (such as, for example, a serial port and a parallel port). In order to perform the function of the electronic parts mounted on the system board, the electronic parts must be electrically interconnected through wires formed during the wiring layer forming process S110. Thus, the wire inspection process S130 is performed after the part mounting process S120 in order to check the electrical interconnection between the electronic parts.

In the wire inspection process S130, it is checked whether the electronic parts mounted on the system board are properly connected via the wires. For instance, it is checked during the wire inspection process S130 whether the wire is open at certain points, whether a short circuit occurs in the wire, or whether a wire defect occurs due to a malfunction of the electronic parts.

The function-test process S140 is performed after the wire inspection process S130 has finished. In the function-test process S140, it is checked whether the electronic parts mounted on the system board are operating properly. Aspects of the present invention directly relate to the function-test process S140.

Although the embodiment shown in FIG. 1 relates to aspects of the present invention as part of a manufacturing process for a system board, the present invention is not limited thereto. Aspects of the present invention can be otherwise employed, such as when assembling a computer, such as a desktop computer or a notebook computer, when using a system board or when inspecting the system board before assembling the computer, or otherwise when assembling interconnected electronic components.

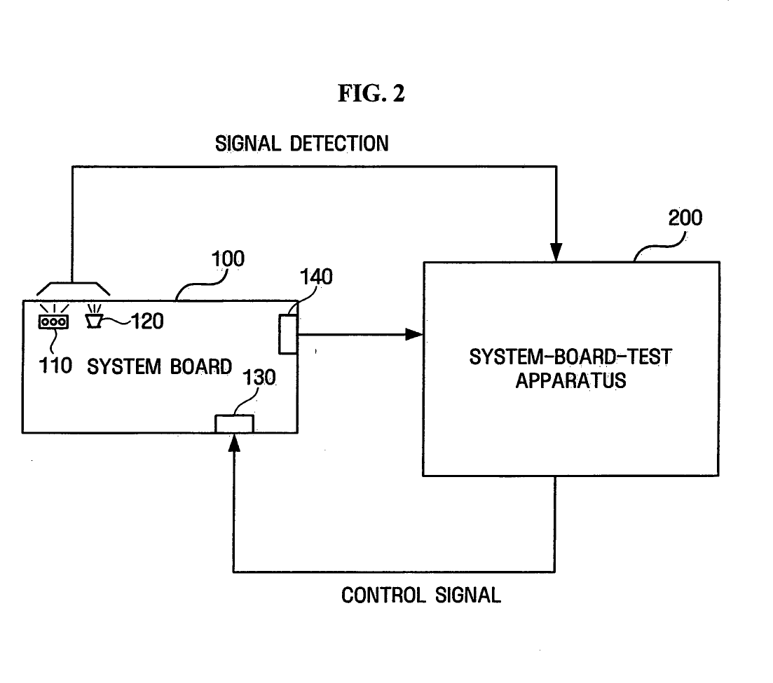

Hereinafter, an apparatus and a method for testing the system board according to and embodiment of the present invention will be described in more detail with reference to FIGS. 2 to 4. FIG. 2 is a schematic view illustrating the relationship between the system board and the system board test apparatus according to one embodiment of the present invention.

The system board test apparatus 200 performs test work for a system board 100 by inputting a control signal into the system board 100. While not required in all aspects, a predetermined program required for the test work (hereinafter, referred to as a “test program”) can be stored in a memory unit (not shown) provided in the system board 100. For instance, the test program can be stored in a hard disk drive (HDD) installed in the system board 100 or a BIOS. When a predetermined control signal is inputted, the test program is executed by means of a CPU (not shown) of the system board 100.

When the test work for the next test item is ready after the test work related to one test item has been completed, the system board 100 notifies the system board test apparatus 200 of the situation. However, where the system board 100 is of a type that does not use a LAN card or a communications application, such as an IEEE 1394 based device or application, in the function-test process S140, the system board 100 can request the control signal by outputting an optical signal using a light-emitting device 110, or by generating a sound signal using a speaker 120 in order to prepare the test work related to the next test item. While shown as having the speaker 120 and the light-emitting device 110, the system board 100 may have only a speaker 120 or only a light emitting device 110, or other emission devices useful for transmitting information.

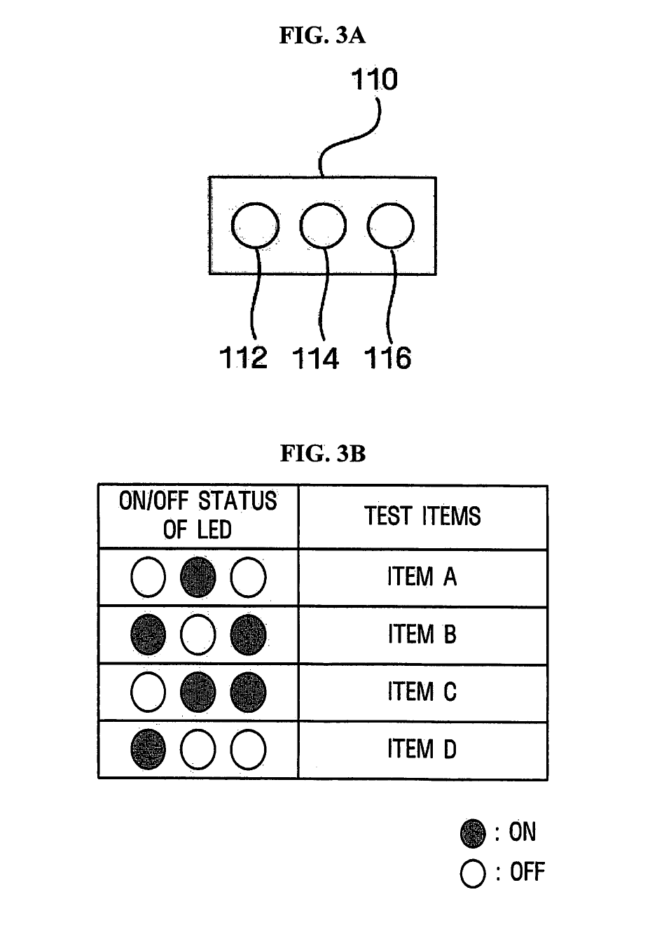

When the light-emitting device 110 is used in order to request the control signal, if the light-emitting device 110 includes three light-emitting diodes 112, 114 and 116, as shown in FIG. 3A, the system board 100 can request the control signal by selectively turning on/off the light-emitting diodes 112, 114 and 116 as shown in FIG. 3B. FIG. 3B shows the on/off status of the light-emitting diodes 112, 114 and 116 and the test items corresponding to the on/off status of the light-emitting diodes 112, 114 and 116. Such an on/off status of the light-emitting diodes 112, 114 and 116 can be maintained until the control signal has been input into the keyboard connector 130 from the system board test apparatus 200. For instance, when the test work related to an item A is necessary, the light-emitting diodes 112, 114 and 116 are maintained in the off-on-off status until the control signal for the test work is input into the keyboard connector 130. It is to be understood that the light-emitting device 110 is not limited to the configuration shown in FIGS. 3A and 3B. In particular, the number of light-emitting diodes 112, 114 and 116 can be greater or lesser than the number shown in FIG. A, and a scheme of correspondence between an on/off status of light-emitting diodes and test items is not limited to what is shown in FIG. 3B.

As shown in FIG. 3B, it is possible to request the control signal by selectively turning on/off the light-emitting diodes 112, 114 and 116 of the light-emitting device 110. However, aspects of the present invention are not limited to the selective turning on/off of the light-emitting diodes 112, 114 and 116. The system board 100 can also request the control signal by adjusting the on/off interval of the light-emitting diodes 112, 114 and 116 of the light-emitting device 110. For example, an optical signal system may be provided wherein, if it is necessary to perform the test work related to the item A, the system board 100 repeatedly and rapidly turns on/off the light-emitting device 110 three times within a predetermined time interval, and if it is necessary to perform the test work related to an item B, the system board 100 repeatedly and slowly turns on/off the light-emitting device 110. In addition, the system board 100 can request the control signal by variously adjusting the output of the optical signal.

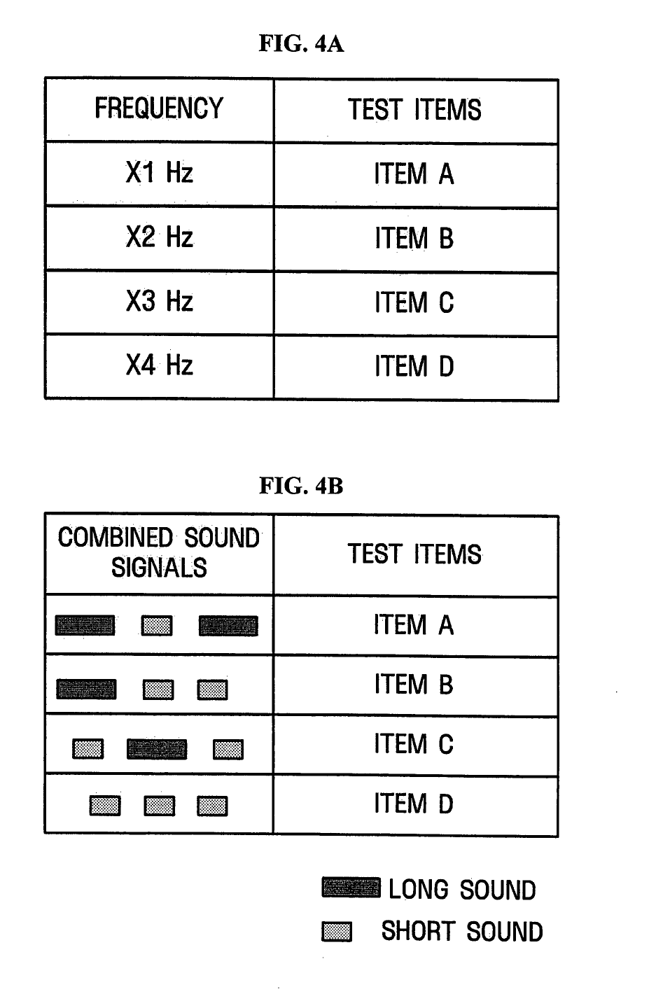

When the system board 100 uses a sound signal, such as a signal from the speaker 120, in order to request the control signal, the system board 100 may request the control signal by adjusting the frequency of the sound signal generated by the speaker 120 as shown in FIG. 4A, which shows examples of correlations between frequencies of the sound signals generated by the speaker 120, and corresponding test items. The speaker 120 can continuously generate the sound signal having the frequency corresponding to the control signal until the control signal has been input into the keyboard connector 130 via the system board test apparatus 200.

In addition, or alternatively, the system board 100 can request the control signal by adjusting the output interval of the sound signals generated by the speaker 120. For instance, as shown in FIG. 4B, the system board 100 can request the control signal based on a combination of short sounds and long sounds. Herein, a long sound refers to a sound signal that is continuously generated for a relatively long period of time at a predetermined level (intensity and frequency), and a short sound refers to a sound signal that is continuously generated for a relatively short period of time at a predetermined level. It is to be understood that the requesting of a test item by use of a sound signal is not limited to the examples shown in FIGS. 4A and 4B and that other types of correspondence between a sound signal and a test item may be used.

Although the above embodiment has been described in such a way that the system board 100 requests the control signal by variously adjusting the optical signals or the sound signals according to the test items, the present invention is not limited thereto. For instance, the system board 100 can use only one signal. In this case, the signal is output whenever the test work for one test item has been completed, thereby requesting the control signal for the test work related to the next test item.

The system board test apparatus 200 detects the signals output from the light-emitting device 110 or the speaker 120 of the system board 100, and then generates the control signal in order to perform the test work for the system board 100. The control signal is input into the system board 100 through the keyboard connector 130 of the system board 100. Further, where data is input through a device other than a keyboard, the connector 130 can be a non-keyboard connector, such as a data port.

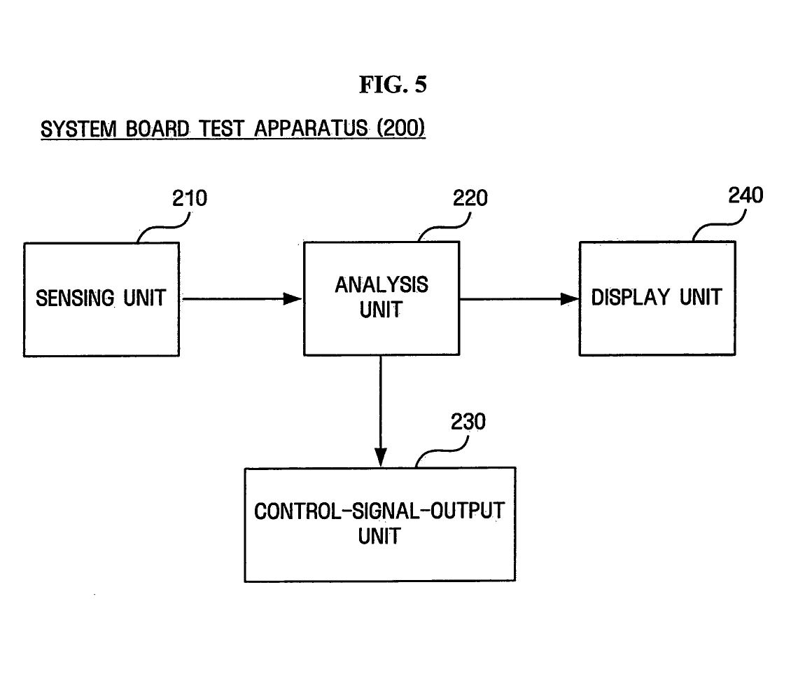

FIG. 5 is a block view illustrating the system board test apparatus 200 according to one embodiment of the present invention. As shown in FIG. 5, the system board test apparatus 200 includes a sensing unit 210, an analysis unit 220, a control-signal-output unit 230 and a display unit 240. The control-signal-output unit 230 and the display unit 240 of the system board test apparatus 200 can be connected to the keyboard connector 130 and the monitor connector 140, respectively, but need not be connected to either in all aspects of the invention.

The sensing unit 210 detects the signal output from the system board 100. For example, the sensing unit 210 may include a light-receiving sensor, such as a photodiode, a photo-transistor transistor, or a CDS, in order to detect an optical signal generated by the light-emitting device 110 of the system board 100. Alternatively or in addition, the sensing unit 210 may include a sound-detecting sensor in order to detect a sound signal generated by the speaker 120 of the system board 100. The sound-detecting sensor may be, for example, an electrodynamic sensor, an electrostatic sensor, a piezoelectric sensor, or a contact-resistant sensor. The sensing unit 210 may have both a light receiving sensor and a sound-receiving sensor in order to detect both types of signals and/or signal combinations.

The analysis unit 220 analyzes the progress of the test work for the system board 100 based on the signals detected by the sensing unit 210. That is, the analysis unit 220 determines whether the system board 100 is ready for the test work related to the next test item and whether the test work for all of the test items has been completed. In addition, based on the test results, the analysis unit 220 determines whether the system board 100 has a defect. To this end, the analysis unit 220 may have information related to the processing state of the test work according to the type of signals detected by the sensing unit 210. For instance, the analysis unit 220 may have information related to the on/off status of the light-emitting device 110 as shown in FIG. 3B or the frequency and combination of sound signals as shown in FIGS. 4A and 4B in order to determine the test item corresponding to the optical signal of the light-emitting device 110 of the system board 100, which is detected by the sensing unit 210. In addition, information corresponding to the optical signals or the sound signals that are generated by the light-emitting device 110 or the speaker 120 of the system board 100 in order to request the control signal can be previously stored in the analysis unit 220. The analysis result of the analysis unit 220, that is, the processing state of the test work for the system board 100, is displayed on the display unit 240 so that the worker can check the processing state of the test work for the system board 100.

The control-signal-output unit 230 outputs the control signal based on the analysis result of the analysis unit 220 in order to perform the test work for the system board 100 related to the next test item. When the system board 100 is connected to the system board test apparatus 200, the control-signal-output unit 230 is connected to the keyboard connector 130 of the system board 100. Preferably, the control signal generated by the control-signal-output unit 230 includes a keyboard input signal, which can be recognized by the system board 100. However, it is to be understood that for other system boards 100, the input signal can be other than a keyboard input signal.

In addition, the control-signal-output unit 230 may include an input device, such as a keyboard emulator or a keyboard. Thus, the worker can input the required control command by using the input device. As the worker inputs the control command through the input device, the control-signal-output unit 230 generates the control signal corresponding to the control command. That is, the control signal is manually output when the test work for the first test item is initiated after the system board 100 has been connected to the system board test apparatus 200. However, after the control signal has been manually output for performing the initial test work, the sensing unit 210 detects the signals output from the light-emitting device 110 or the speaker 120 of the system board 100, and the analysis unit 220 analyzes the signals detected by the sensing unit 210 in such a manner that the control-signal-output unit 230 can automatically output the control signal for the test work related to the next test item.

Meanwhile, the system board 100 can output information related to the processing state of the test work and the test result for each test item through the monitor connector 140. Such information can be displayed on the display unit 240 connected to the monitor connector 140.

The above functional units of the system board test apparatus 200 shown in FIG. 5 can be embodied as modules. The term “module” refers to a software component or a hardware component, such as an FPGA (field programmable gate array) or an ASIC (application specific integrated circuit), used for performing a predetermined function. The module can be stored in an addressable storage medium or can be designed such that it executes at least one processor. For instance, the module can include software components, object-oriented software components, class components and task components. In addition, the module may include processes, functions, attributes, procedures, sub-routines, segments of program code, drivers, firmware, microcode, circuits, data, databases, data structures, tables, arrays and parameters. The above components and functions implemented by the modules can be combined or sub-divided into additional components and functions.

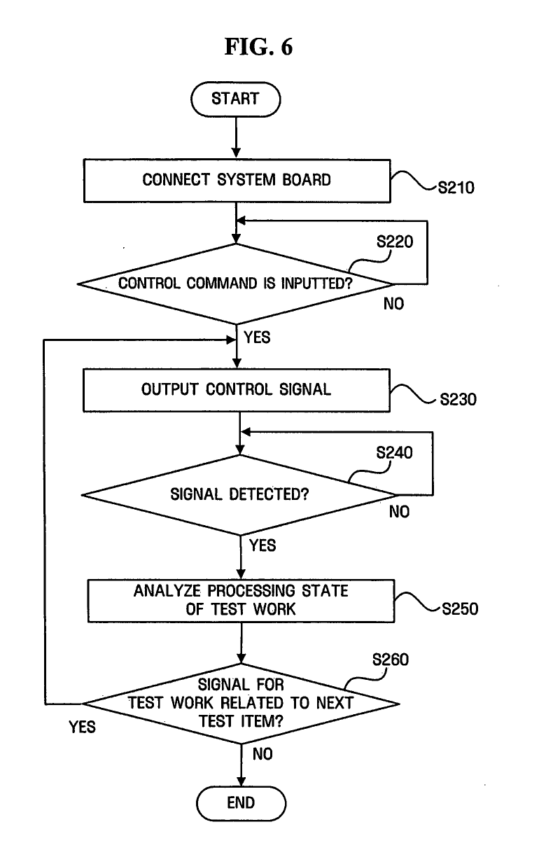

FIG. 6 is a flowchart illustrating the procedure for testing the system board according to an embodiment of the present invention. First, when the system board 100, which is subject to the test work, is connected to the system board test apparatus 200 in S210, the control-signal-output unit 230 waits for the control command input from the worker. When the system board 100 is connected to the system board test apparatus 200, the control-signal-output unit 230 and the display unit 240 of the system board test apparatus 200 are connected to the keyboard connector 130 and the monitor connector 140, respectively. It is to be understood that in other aspects, the connectors 130 and 140 can be through a common input/output port.

If the worker inputs the control command in S220 using the input device, such as a keyboard emulator or the keyboard, the control-signal-output unit 230 outputs the control signal to the system board 100 in S230. The control signal is transmitted to the keyboard connector 130. Preferably, but not necessarily, the control signal is in the form of a keyboard input signal.

When the control signal is input into the system board 100, the test work for the system board 100 is performed. When the test work for one test item has been completed, the signal requesting the control signal required for the test work related to the next test item is generated, such as through the light-emitting device 110 and/or the speaker 120.

When the system board 100 outputs the signal, the sensing unit 210 detects the signal in S240. At this time, the type of signals detected by the sensing unit 210 may vary depending on particular applications. For example, the sensing unit 210 may detect the optical signal generated by the light-emitting device 110 of the system board 100 or, alternatively, may detect the sound signal generated by the speaker 120 of the system board 100.

The analysis unit 220 analyzes the processing state of the test work for the system board 100 based on the signal detected by the sensing unit 210 in S240. If it is determined in S260 by the analysis unit 220 that the signal detected by the sensing unit 210 requests the control signal that is required for the test work related to the next test item, the control-signal-output unit 230 outputs the control signal such that the test work for the next test item can be performed, as indicated by the return to S230 in FIG. 6.

However, if it is determined by the analysis unit 220 that the test work has been completed for all test items of the system board 100, or if an error occurs in the system board 100, the test work for the system board 100 can be terminated. In such a case, the analysis unit 220 determines that a signal is not detected by the sensing unit requesting a control signal for another test item. At this time, the analysis unit 220 can direct the display unit 240 to display the test item being executed, the error, if present, and an item inquiring about terminating the test work.

As described above, the apparatus and the method for testing the system board according to aspects of the present invention have the following advantages. The test work for the system board can be performed through an automatic process. The time required for testing the system board can be shortened. It is possible to improve the efficiency of production of the system board and the computing device using the system board. However, additional advantages are apparent or can learned from aspects of the invention.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. An apparatus that tests a system board, comprising:
a sensing unit that detects a predetermined signal output from the system board; and
a control-signal-output unit that outputs a predetermined control signal to the system board to perform a test in correspondence with the predetermined signal detected by the sensing unit.

2. The apparatus of claim 1, further comprising an analysis unit that analyzes a processing state of test work for the system board based on the signal detected by the sensing unit, wherein the control-signal-output unit outputs the predetermined control signal according to an analysis result of the analysis unit.

3. The apparatus of claim 1, wherein the control signal includes information that orders test work for the system board.

4. The apparatus of claim 1, wherein the predetermined signal output from the system board is an optical signal, and the sensing unit includes a light-receiving sensor that detects the optical signal.

5. The apparatus of claim 4, wherein the control-signal-output unit outputs the control signal according to an on/off state and/or an on/off interval of a light-emitting device of the system board that generates the optical signal.

6. The apparatus of claim 1, wherein the predetermined signal output from the system board is a sound signal, and the sensing unit includes a sound-detecting sensor for detecting the sound signal.

7. The apparatus of claim 6, wherein the control-signal-output unit outputs the control signal according to a frequency and/or an output interval of the sound signal.

8. A method of testing a system board, comprising:
detecting a predetermined signal output from the system board; and
outputting a predetermined control signal to the system board in correspondence with the detected predetermined signal.

9. The method of claim 8, further comprising analyzing a processing state of test work for the system board based on the detected predetermined signal, wherein the predetermined control signal is output according to an analysis result of an analysis unit.

10. The method of claim 8, wherein the predetermined control signal includes information ordering test work for the system board.

11. The method of claim 8, wherein the predetermined signal output from the system board is an optical signal.

12. The method of claim 11, wherein the predetermined control signal is output according to an on/off state and/or an on/off interval of a light-emitting device of the system board generating the optical signal.

13. The method of claim 11, wherein the predetermined signal output from the system board is a pattern of on/off states and/or on/off intervals of a plurality of light emitting devices, and wherein the predetermined control signal is output according to the pattern of on/off states and/or on/off intervals of the plurality of light emitting devices.

14. The method of claim 8, wherein the predetermined signal output from the system board is a sound signal.

15. The method of claim 14, wherein the predetermined control signal is output according to a frequency or an output interval of the sound signal.

16. A system board, comprising:
electrical parts including a memory unit, a processor, and an emission device; and
wiring interconnecting the memory unit, the processor, and the emission device,
wherein the memory stores a predetermined program encoded with a test method implemented by the processor, the test method comprising, when the system board is connected to an apparatus that tests the system board, the processor performs the predetermined program required to initiate a test work and outputs a predetermined signal through the emission device to the apparatus to perform at least one test included in the test work to be performed on the system board.

17. The system board of claim 16, wherein the emission device includes a light emitting device, and the predetermined signal output is encoded in an optical signal output from the light emitting device.

18. The system board of claim 16, wherein the emission device comprises a plurality of light-emitting devices, and the predetermined signal output through the emission device comprises a pattern of on/off states and/or on/off intervals of the plurality of light emitting devices.

19. The system board of claim 16, wherein the emission device includes a sound-emitting device, and the predetermined signal output is encoded in the sound signal.

20. The system board of claim 16, wherein the emission device encodes the predetermined signal output in a series of signals and/or in signals of varying strength.
